(19) United States
(12) Patent Application Publication
(10) Pub. No.: US 2023/0021136 A1
(43) Pub. Date: Jan. 19, 2023

(54) PHOTOMASK AND PHOTOMASK FIXING DEVICE

(71) Applicant: CHANGXIN MEMORY TECHNOLOGIES, INC., Hefei (CN)

(72) Inventor: KUAN-TING CHOU, Hefei (CN)

(21) Appl. No.: 17/464,682

(22) Filed: Sep. 2, 2021

Related U.S. Application Data
(63) Continuation of application No. PCT/CN2021/106750, filed on Jul. 16, 2021.

(30) Foreign Application Priority Data
Jul. 13, 2021 (CN) 202110789539.X

(51) Int. Cl. G03F 1/60; G03F 7/20; G03F 1/64

(52) U.S. Cl. CPC G03F 1/60; G03F 7/70825; G03F 1/64; G03F 7/707; G03F 7/70733

(57) ABSTRACT

Embodiment discloses a photomask and a photomask fixing device. The photomask includes a photomask body. The photomask body includes a first side surface and a second side surface arranged in parallel, and a pattern surface connecting the first side surface and the second side surface. The first side surface and the second side surface are respectively provided with a plurality of fixing holes configured for fitting with a fixing portion to fix the photomask body. In the above photomask, two parallel side surfaces positioned on the pattern surface are used as fixing surface of the photomask, i.e., the first side surface and the second side surface. The first side surface and the second side surface are respectively provided with a plurality of fixing holes configured for fitting with the fixing portion configured to fix the photomask, to strengthen fixation of the photomask.

### CROSS-REFERENCE TO RELATED APPLICATION

This application is a continuation of PCT/CN2021/106750, filed on Jul. 16, 2021, which claims priority to Chinese Patent Application No. 202110789539.X titled “PHOTOMASK AND PHOTOMASK FIXING DEVICE” and filed to the State Intellectual Property Office on Jul. 13, 2021, the entire contents of which are incorporated herein by reference.

### TECHNICAL FIELD

The present disclosure relates to the field of photomask material design technologies, and more particularly, to a photomask and a photomask fixing device.

### BACKGROUND

As an important process step in semiconductor fabrication, a photolithographic process is a process for transferring patterned layers on a photomask to substrates. Areas of the photomask fixed to a machine are two side edges of the photomask. To ensure that the photomask is firmly fixed, a larger area is required to fix the photomask by means of vacuum suction or mechanical chuck. The vacuum suction is as shown in FIG. 1, the photomask 001 needs to be provided with a plurality of vacuum chucks 002. The mechanical chuck 003 is as shown in FIG. 2, the mechanical chuck 003 needs to clamp upper and lower surfaces of the photomask 001, which may reduce a usable area of the photomask 001.

### SUMMARY

The present disclosure discloses a photomask and a photomask fixing device, to strengthen fixation of the photomask and release more usable space for the photomask.

To achieve the above objective, the present disclosure provides following technical solutions.

In a first aspect, the present disclosure provides a photomask, which includes a photomask body. The photomask body includes a first side surface and a second side surface arranged in parallel, and a pattern surface connecting the first side surface and the second side surface.

The first side surface and the second side surface are respectively provided with a plurality of fixing holes configured for fitting with a fixing portion to fix the photomask body.

In the above photomask, two parallel side surfaces positioned on the pattern surface are used as fixing surface of the photomask, i.e., the first side surface and the second side surface. The first side surface and the second side surface are respectively provided with a plurality of fixing holes configured for fitting with the fixing portion configured to fix the photomask, to strengthen fixation of the photomask. Compared with fixing the photomask by means of vacuum suction, there is no need to additionally provide a vacuum chuck on the pattern surface of the photomask, and thus it does not occupy space of the pattern surface of the photomask, such that the photomask has extra space for use, such as increasing number of times of alignment or saving time. Compared with fixing the photomask by means of the mechanical chuck, the chuck needs to clamp the pattern surface and the other surface parallel to the pattern surface. In contrast, the above-mentioned photomask only occupies space of the first side surface and the second side surface, thus releasing more usable space of the pattern surface of the photomask.

In a second aspect, the present disclosure also provides a device for fixing the photomask according to the first aspect. The device includes a columnar fixing portion configured for interference fit with each of the plurality of fixing holes of the photomask.

### BRIEF DESCRIPTION OF THE DRAWINGS

FIG. 1 is a schematic structural diagram of a photomask fixed by means of vacuum suction;

FIG. 2 is a schematic structural diagram of a photomask fixed by means of a mechanical chuck;

FIG. 3 is a schematic structural diagram of a photomask according to an embodiment of the present disclosure;

FIG. 4a to FIG. 4e illustrate schematic structural diagrams of a plurality of fixing holes in a photomask according to embodiments of the present disclosure;

FIG. 5 is a schematic structural diagram of a photomask fixing device according to an embodiment of the present disclosure; and

FIG. 6 is a schematic assembly diagram of a photomask fixing device according to an embodiment of the present disclosure.

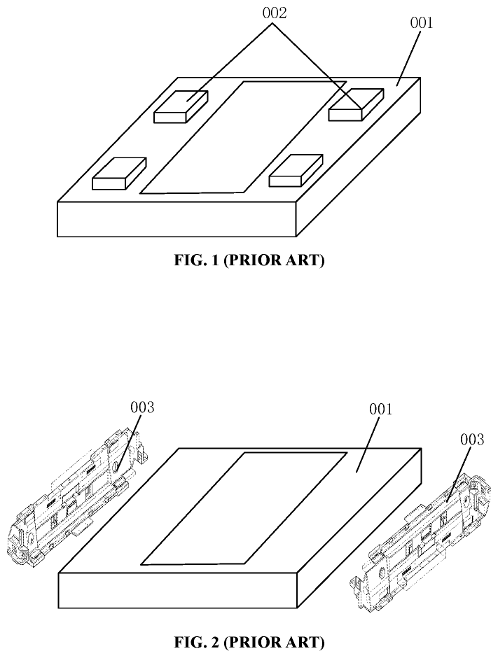

Reference numerals in the accompanying drawings: 001—photomask; 002—vacuum chuck; 003—chuck; 100—photomask body; 110—first side surface; 120—second side surface; 130—pattern surface; 200—fixing hole; and 300—fixing portion.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

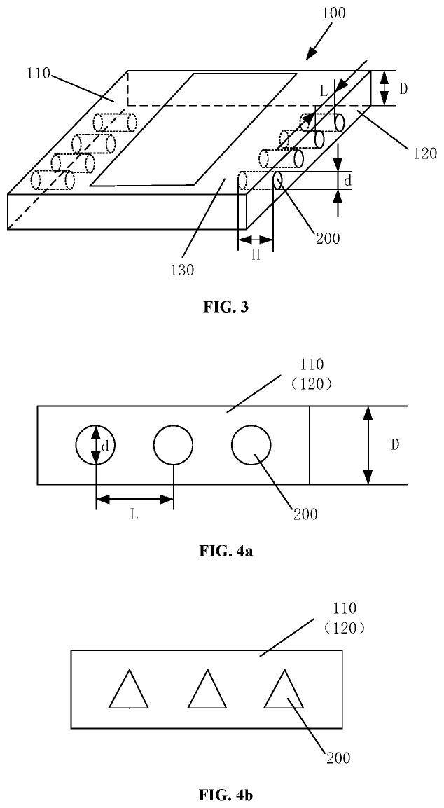

As shown in FIG. 3, an embodiment of the present disclosure provides a photomask, which includes a photomask body 100. The photomask body 100 includes a first side surface 110 and a second side surface 120 arranged in parallel, and a pattern surface 130 connecting the first side surface 110 and the second side surface 120. The first side surface 110 and the second side surface 120 are respectively provided with a plurality of fixing holes 200 configured for fitting with a fixing portion 300 to fix the photomask body 100.

In the above photomask, two parallel side surfaces positioned on the pattern surface 130 are used as fixing surface of the photomask, i.e., the first side surface 110 and the second side surface 120. The first side surface 110 and the second side surface 120 are respectively provided with a plurality of fixing holes 200 configured for fitting with the fixing portion 300 configured to fix the photomask, to strengthen fixation of the photomask. Compared with fixing the photomask by means of vacuum suction, there is no need to additionally provide a vacuum chuck on the pattern surface 130 of the photomask, and thus it does not occupy space of the pattern surface 130 of the photomask, such that the photomask has extra space for use, such as increasing number of times of alignment or saving time. Compared with fixing the photomask by means of the mechanical chuck, the chuck needs to clamp the pattern surface 130 and the other surface parallel to the pattern surface 130. In contrast, the above-mentioned photomask only occupies space of the first side surface 110 and the second side surface 120, thus releasing more usable space of the pattern surface 130 of the photomask. Therefore, there is no need to reserve a fixed region on the pattern surface 130 of the photomask, and only a physical form is improved. Thus, on the basis of strengthening the fixation, more space of the photomask can be released to achieve other functions.

In one embodiment, number of the fixing holes 200 on the first side surface 110 and/or the second side surface 120 is three to eight. For example, the number of the fixing holes 200 on the first side surface 110 may be three, four, five, six, seven or eight. The number of the fixing holes 200 on the second side surface 120 may be three, four, five, six, seven or eight.

It is to be noted that the number of the fixing holes 200 on the first side surface 110 and the number of the fixing holes 200 on the second side surface 120 may be equal or may be different.

Structures of the fixing holes 200 are described in detail below.

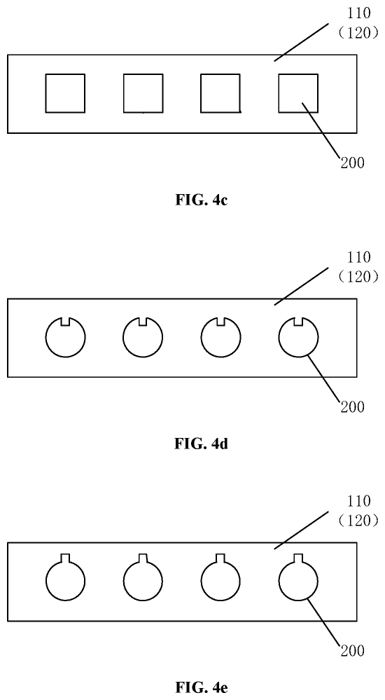

In one embodiment, with reference to FIG. 3 or FIG. 4a, a pitch L between two adjacent fixing holes is 8 mm to 20 mm. For example, the pitch L may be 8 mm, 10 mm, 12 mm, 14 mm, 16 mm, 18 mm, or 20 mm. On the basis of not damaging a strength of the photomask itself, stability of the plurality of fixing holes 200 can be improved.

In one embodiment, a depth H of the plurality of fixing hole 200 ranges from 1.5 mm to 2.5 mm. For example, the depth H may be 1.5 mm, 1.6 mm, 1.7 mm, 1.8 mm, 1.9 mm, 2.0 mm, 2.1 mm, 2.2 mm, 2.3 mm, 2.4 mm, or 2.5 mm. With continued reference to FIG. 3, to ensure the stability of the photomask, the depth of each of the plurality of fixing holes 200 should not be too small. However, if the depth of each of the plurality of fixing holes 200 is too large, this may have a negative effect on design of patterns on the pattern surface 130 of the photomask, which may cause failure of normal utilization of patterns at an edge of the photomask, or may cause waste of an active area of the pattern surface 130 resulted from keeping away from the plurality of fixing holes 200 when designing the patterns on the pattern surface 130.

It is to be noted that the plurality of fixing holes 200 are mainly configured to fit with the fixing portion 300 to fix the photomask, so any hole-shaped structure that can implement this function may be referred to as the fixing holes 200 mentioned in this embodiment. That is, the fixing holes 200 mentioned in this embodiment may be various holes.

In one embodiment, with reference to FIG. 3 and FIG. 4a, the fixing holes 200 are circular holes. The number of fixing holes 200 in FIG. 3 is four, and the number of fixing holes 200 in FIG. 4a is three. The circular holes have smooth outer rings, which facilitates insertion and withdrawal of the fixing portion 300.

In one embodiment, a thickness D of the photomask body 100 and a diameter d of each of the plurality of fixing holes 200 satisfy a relational expression: 1.5d≤D≤3d. With reference to FIG. 3 or 4a, a ratio of the thickness of the photomask to the diameter of each of the plurality of fixing holes 200 is 1.5:1, or 2:1, or 3:1, etc. In this way, the stability of each of the plurality of fixing holes 200 can be improved without damaging the strength of the photomask itself.

In one embodiment, the diameter d of each of the plurality of fixing holes 200 ranges from 2.5 mm to 3.5 mm. For example, the diameter d may be 2.5 mm, 2.6 mm, 2.7 mm, 2.8 mm, 2.9 mm, 3.0 mm, 3.1 mm, 3.2 mm, 3.3 mm, 3.4 mm, or 3.5 mm. The diameter of each of the plurality of fixing holes 200 may be uniform or may be not uniform. That is, the diameter of each of the plurality of fixing holes 200 may be equal or may be different. In addition, the diameter of each of the plurality of fixing holes 200 may gradually become smaller or larger along a depth direction.

In one embodiment, the plurality of fixing holes 200 are polygonal holes. For example, in FIG. 4b and FIG. 4c, shapes of the fixing holes 200 in FIG. 4b are triangles, the triangular holes can prevent the photomask from rotating around the fixing portion 300, and the number of the fixing holes 200 is three. Shapes of the fixing holes 200 in FIG. 4c are rectangles, and the number of rectangular holes is four. It is to be understood that the polygonal holes are not limited to triangles and rectangles, and may also be other quadrilaterals, pentagons, hexagons, and the like.

In one embodiment, the plurality of fixing holes 200 are polygonal holes such as holes in FIG. 4d and FIG. 4e, but are not limited to shapes of the holes in FIG. 4d and FIG. 4e. These polygonal holes can implement accurate positioning between the plurality of fixing holes 200 and the fixing portion 300.

In one embodiment, an inner wall of each of the plurality of fixing holes 200 has at least one convex tooth. With reference to FIG. 4d and FIG. 4e, in FIG. 4d, the inner wall of each of the plurality of fixing holes 200 has a convex tooth fitting with a groove on the fixing portion 300 to implement the positioning. In FIG. 4e, the inner wall of each of the plurality of fixing holes 200 has a recess structure fitting with a bulge on the fixing portion 300 to implement the accurate positioning.

In one embodiment, the plurality of fixing holes 200 on the first side surface 110 and the plurality of fixing holes 200 on the second side surface 120 may be arranged symmetrically or alternately.

In one embodiment, the plurality of fixing holes 200 on the first side surface 110 are uniformly arranged, and arrangement modes of the plurality of fixing holes 200 on the second side surface 120 are not limited. In some embodiments, the plurality of fixing holes 200 on the second side surface 120 are uniformly arranged, and arrangement modes of the plurality of fixing holes 200 on the first side surface 110 are not limited. In some embodiments, the plurality of fixing holes 200 on the first side surface 110 are uniformly arranged, and the plurality of fixing holes 200 on the second side surface 120 are uniformly arranged.

In the above-mentioned photomask, different fixation methods based on physical structures are employed to increase stability of mechanical actions of the photomask in the machine, and these fixation methods are performed in smaller space, such that restrictions on fixed movement of the photomask in the machine are relaxed, only two side surfaces of the photomask need to be restricted, and the area of the pattern surface 130 is not occupied, and thus available space of the photomask is increased.

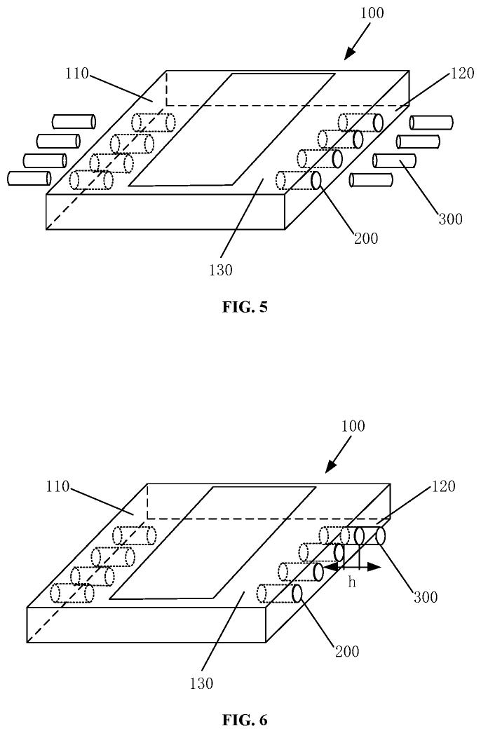

In a second aspect, with reference to FIG. 5, based on the same inventive concept, an embodiment of the present disclosure also provides a device for fixing the photomask according to the first aspect. The device includes a columnar fixing portion 300 configured for interference fit with each of the plurality of fixing holes 200 of the photomask.

It is to be noted that the shape, size, and number of the fixing portion 300 are matched with arrangement of the plurality of fixing holes 200 to fix the photomask more stably. Furthermore, the plurality of fixing holes 200 on the photomask can also implement the positioning.

In one embodiment, the columnar fixing portion 300 is mounted on a machine. The above photomask fixing device adopts a traditional fixation method by means of bolts, eliminating the need for high-precision machine equipment and eliminating the need to design the vacuum chuck, such that equipment costs can be reduced and more space can be released for use, such as increasing number of times of alignment or saving time. This device only improves a physical form, and thermal simulation of the photomask is more accurate.

In one embodiment, a diameter of the fixing portion 300 ranges from 2.5 mm to 3.5 mm. For example, the diameter may be 2.5 mm, 2.6 mm, 2.7 mm, 2.8 mm, 2.9 mm, 3 mm, 3.1 mm, 3.2 mm, 3.3 mm, 3.4 mm, or 3.5 mm. The diameter of the fixing portion 300 fits with that of each of the plurality of circular fixing holes 200 on the photomask.

In one embodiment, with reference to FIG. 6, a length h of the fixing portion 300 inserted into each of the plurality of fixing holes 200 is 1 mm to 2 mm. For example, the length h may be 1 mm, 1.2 mm, 1.4 mm, 1.6 mm, 1.8 mm, or 2.0 mm.

It is to be noted that the fixing portion 300 may be columnar, or may have a structure with a larger end and a smaller end.

In one embodiment, when the inner wall of each of the plurality of fixing holes 200 has a convex tooth, the fixing portion 300 has a groove fitting with the convex tooth. For example, when the photomask adopts the structure as shown in FIG. 4d, the inner wall of each of the plurality of fixing holes 200 has a convex tooth, the fixing portion 300 has a groove fitting with the convex tooth to implement the positioning. When the photomask adopts the structure as shown In FIG. 4e, the inner wall of each of the plurality of fixing holes 200 has a recess structure, and the fixing portion 300 has a bulge fitting with the recess structure to implement the accurate positioning.

In one embodiment, materials of the fixing portion 300 are polymer materials such as plastic, rubber, or polyurethane, which have better heat resistance, such that the thermal simulation of the photomask is more accurate.

Those skilled in the art should realize that the embodiments of the present disclosure may be provided as a method, a system or a computer program product. Therefore, the present disclosure may adopt the form of full hardware embodiments, full software embodiments or embodiments in combination of software and hardware. Furthermore, the present disclosure may use forms of computer program products implemented on one or more computer storage media (including but not limited to a magnetic disk memory, a CD-ROM, an optical memory or the like) which includes a computer program code.

The present disclosure is described in reference to the flowchart and/or block diagram of a method, a device (system) or a computer program product according to the embodiments of the present disclosure. It is to be understood that each flow and/or block in the flowchart and/or block diagram as well as combination of flow and/or block in the flowchart and/or block diagram may be realized by computer program instructions. These computer program instructions may be provided for a general-purpose computer, a special-purpose computer, an embedded processor or processors of other programmable data processing terminal equipment to generate a machine, so as to generate an apparatus configured to implement designated functions in one or more flows of a flowchart and/or one or more blocks of a block diagram by means of instructions executed by a computer or a processor of other programmable data processing equipment.

These computer program instructions may also be stored in a computer-readable memory that can guide a computer or other programmable data processing equipment to work in a particular way, so that the instructions stored in the computer-readable memory generate a manufactured product including a command device that implements the designated functions in one or more flows of a flowchart and/or one or more blocks of a block diagram.

These computer program instructions may also be loaded on a computer or other programmable data processing equipment, to execute a series of operating steps on the computer or other programmable equipment to generate treatments implemented by the computer, so that instructions executed on the computer or other programmable equipment provide steps configured to implement designated functions in one or more flows of a flowchart and/or one or more blocks of a block diagram.

Although some embodiments of the present disclosure have been described, those skilled in the art may make additional alterations and modifications on these embodiments as soon as they know the basic creative concept. Therefore, the appended claims are intended to be interpreted as comprising some embodiments and all alterations and modifications falling within the scope of the present disclosure.

Apparently, a person skilled in the art can make various modifications and variations on the embodiments of the present disclosure without departing from the spirit and scope of the embodiments of the present disclosure. In this way, if these modifications and variations of the embodiments of the present disclosure fall within the scope of the claims of the present disclosure and equivalent technologies thereof, the present disclosure also intends to include these modifications and variations.

What is claimed is:

1. A photomask comprising a photomask body, the photomask body comprising a first side surface and a second side surface arranged in parallel, and a pattern surface connecting the first side surface and the second side surface;
the first side surface and the second side surface being respectively provided with a plurality of fixing holes configured for fitting with a fixing portion to fix the photomask body.

2. The photomask according to claim 1, wherein number of the plurality of fixing holes on the first side surface and/or the second side surface is three to eight.

3. The photomask according to claim 1, wherein the plurality of fixing holes are circular holes.

4. The photomask according to claim 3, wherein a relationship between a thickness D of the photomask body and a diameter d of each of the plurality of fixing holes satisfies: 1.5d≤D≤3d.

5. The photomask according to claim 4, wherein the diameter d of each of the plurality of fixing holes is 2.5 mm to 3.5 mm.

6. The photomask according to claim 1, wherein the plurality of fixing holes are polygonal holes or irregularly-shaped holes.

7. The photomask according to claim 1, wherein a pitch L between adjacent two of the plurality of fixing holes is 8 mm to 20 mm.

8. The photomask according to claim 1, wherein a depth H of each of the plurality of fixing holes ranges from 1.5 mm to 2.5 mm.

9. The photomask according to claim 1, wherein the plurality of fixing holes on the first side surface are symmetrically arranged with respect to the plurality of fixing holes on the second side surface.

10. The photomask according to claim 1, wherein the plurality of fixing holes on the first side surface are arranged uniformly; or
the plurality of fixing holes on the second side surface are arranged uniformly.

11. The photomask according to claim 1, wherein an inner wall of each of the plurality of fixing holes has at least one convex tooth.

12. A device for fixing a photomask, the photomask comprising a photomask body;
wherein the photomask body comprises a first side surface and a second side surface arranged in parallel, and a pattern surface connecting the first side surface and the second side surface;
wherein the first side surface and the second side surface are respectively provided with a plurality of fixing holes;
wherein the device comprises a columnar fixing portion configured for interference fit with each of the plurality of fixing holes of the photomask.

13. The device according to claim 12, wherein a length h of the fixing portion inserted into each of the plurality of fixing holes is 1 mm to 2 mm.

14. The device according to claim 12, wherein when an inner wall of each of the plurality of fixing holes has a convex tooth, the fixing portion has a groove configured for fitting with the convex tooth.

15. The device according to claim 12, wherein a material of the fixing portion is plastic, rubber or polyurethane.
